(19) United States
(12) Patent Application Publication
(10) Pub. No.: US 2007/0162796 A1
(43) Pub. Date: Jul. 12, 2007

(54) Method and portable device for testing electronic device

(75) Inventors: Cheng Che Chan, Banciao City (TW); Chuan-Kun Wang, Hsinchu City (TW); Ying-Feng Huang, Luchau Hsiang (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Mediatek Inc.

(21) Appl. No.: 11/329,306

(22) Filed: Jan. 10, 2006

(51) Int. Cl. G01R 31/28

(52) U.S. Cl. 714/724

(57) ABSTRACT

Portable device capable of testing an electronic device is disclosed. An embodiment of a portable device comprises a memory device and a processing unit. The memory device stores a test program describing a test flow including a series of test instructions. The processing unit, coupled to the memory device, acquires the test program, transmits the test command to the electronic device to direct the electronic device sequentially perform the test commands.

### BACKGROUND

The invention relates to testing, and more particularly, to methods and devices for testing electronic device.

Electronic devices such as optical disk drives, mobile phones, personal digital assistants (PDAs) and similar, are tested via personal computers (PCs) incorporated with particular debugging interface. FIG. 1 is a diagram of conventional testing environment 10, comprising a PC 11 and an electronic device 15. The PC 11 issues a series of commands to the electronic device 15. The commands are then executed by the electronic device 15 for performing specific testing scenarios. The testing results and error messages are received by the PC 11. Testing is costly, however, as one tested device requires one PC.

### SUMMARY

Portable devices capable of testing an electronic device are provided. An embodiment of a portable device comprises a connection port, a memory device, such as a flash memory, and a processing unit. The memory device stores a test program describing a test flow including a series of test instructions. The processing unit, coupled to the memory device, acquires the test program, sequentially converts the test instructions into a series of test commands recognized by the electronic device, transmits the converted test commands to the electronic device to direct the electronic device to perform the test commands sequentially. The host of the electronic device may be disabled prior to transmission of the test commands.

An embodiment of a processing unit further receive a test result or an error message generated by the electronic device and store the received test result or error message in the memory device. The test result or error message comprises information regarding the execution status for the generated test commands. The processing unit may further examine the received test result or error message to control the test flow.

An embodiment of a portable device may further comprise an output module. An embodiment of an output module may comprise a small liquid crystal display (LCD) screen to display information about the received test result or error message in real-time. The output module may comprise two lamps or Light Emitting Diodes (LEDs) of different color. The processing unit may further direct the output module to provide information about the received test result or error message. The processing unit may further direct at least a lamp or LED to emit light when the test result is received, and direct the other lamp or LED to emit light of a different color when the error message is received.

The processing unit may further sequentially generate a series of test messages respectively comprising a header comprising information regarding that the generated test message comprises a test command to be executed, and one of the converted test commands, and transmit the generated test messages to the electronic device.

The portable device may further comprise a connection port. The processing unit may further transmit the generated test messages to the electronic device via the connection port. The connection port is preferably compatible with RS232, Integrated Drive Electronics (IDE), Universal Serial Bus (USB) or Small Computer System Interface (SCSI).

Methods for testing an electronic device, performed by a processing unit of a portable test device, are provided. An embodiment of a method for testing an electronic device comprises the following steps. A test program describing a test flow including a series of test instructions is acquired. The test instructions are sequentially converted into a series of test commands recognized by the electronic device in the course of the test flow. The converted test commands are transmitted to the electronic device to direct the electronic device sequentially execute the test commands. The host of the electronic device is disabled prior to transmission of the test commands.

The portable test device is preferably not a general-purpose workstation, desktop or laptop computer.

An embodiment of a method for testing an electronic device may further comprise the steps described in the following. A test result or an error message generated by the electronic device is received during execution of the test commands. The received test result or error message is stored in a memory device of the portable test device. The test result or error message comprises information regarding the execution status for the generated test commands, and may be further examined to control the test flow.

An embodiment of a method for testing an electronic device may further comprise directing an output module of the portable test device to provide information about the received test result or error message.

An embodiment of a method for testing an electronic device may further comprise directing a small liquid crystal display (LCD) screen of the portable test device to display information about the received test result or error message in real-time.

An embodiment of a method for testing an electronic device may further comprise directing one lamp or Light Emitting Diode (LED) of the portable test device to emit light when the test result is received, and directing another lamp or LED of the portable test device to emit different light when the error message is received.

An embodiment of a method for testing an electronic device may further comprise steps as described in the following. A series of test messages are sequentially generated, respectively comprising a header comprising information regarding that the generated test message comprises a test command to be executed, and one of the converted test commands. The generated test messages are transmitted to the electronic device

The generated test commands are preferably compatible with an Integrated Drive Electronics/AT Attachment Packet Interface (IDE/ATAPI) specification. The test message preferably comprises a checksum, utilized to ensure that the test message is transmitted without error.

### DESCRIPTION OF THE DRAWINGS

The invention will become more fully understood by referring to the following detailed description of embodiments with reference to the accompanying drawings, wherein:

FIG. 1 is a diagram of the conventional testing environment;

FIG. 2 is a diagram of an embodiment of a test system;

FIG. 3 is a diagram of an exemplary test message;

FIGS. 4 and 5 illustrate flowcharts of embodiments of methods for testing electronic devices.

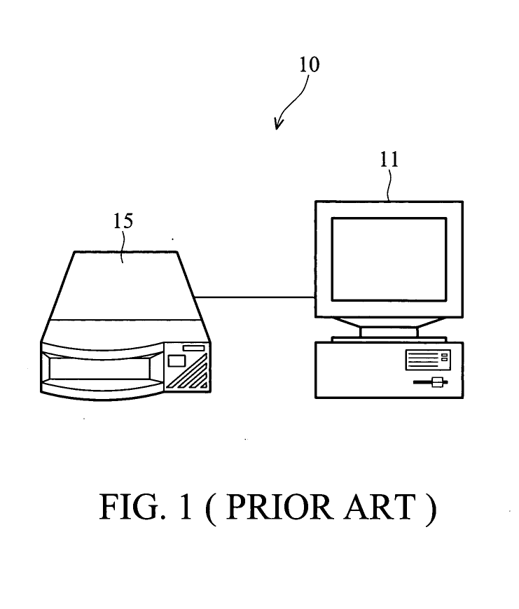

### DESCRIPTION

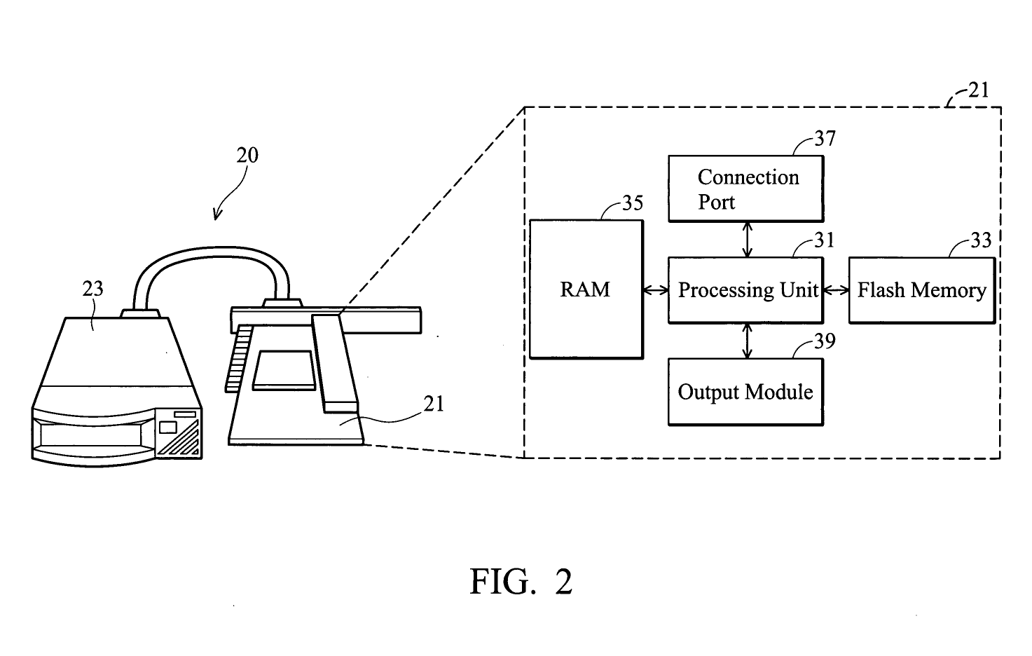

FIG. 2 is a diagram of an embodiment of a portable testing device 21 and an electronic device 23. The portable testing device 21 comprises CPU chips, but, is not general-purpose workstations, desktops, or laptop computers. The portable testing device 21 typically uses microprocessors, or use custom-designed chips or both. The electronic device 23 may be used in an automobile, plane, train, space vehicle, machine tool, camera, digital video recorder (DVR), consumer and office appliance, cellphone, PDA or other handheld device as well as robot or toy.

The portable testing device 21 comprises a processing unit 31, a flash memory 33, a random access memory (RAM) 35, a connection port 37, and an output module 39. The connection port 37 may be a serial port compatible with RS232, Universal Serial Bus (USB), IEEE 1394, or similar, or a parallel port compatible with Integrated Drive Electronics (IDE), Small Computer System Interface (SCSI), IEEE 1284, or similar. The portable testing device 21 establishes a connection with the electronic device 23 by the connection port 37, and then can transmit/receive signal to/from the electronic device 23 via the connection.

In one embodiment, at least one test program for a specific test scenario is stored in the flash memory 33 or RAM 35. For example, when a DVR is tested, three test programs respectively for scenarios of reading, writing and seeking data on an optical storage medium may the stored. In another embodiment, the memory directly stored at least one test code/instruction to be executed. The test program provided by a client or an operator is preferably stored in the flash memory 33 capable of retaining the program after power-down to eliminate extra loading effort. The test program describes a test flow including a series of test instructions. The test instruction means a set of codes or words can be interpreted to a specific test process.

The processing unit 31 such as a microprocessor or custom-designed chip receives a selection signal, selects one test program from multiple stored test programs contingent upon the selection signal. In one embodiment, said selection signal could be hardware, such as a jumper or a switch, that can be detected by the processing unit 31 and the processing unit 31 make a selection accordingly. In another embodiment, the selection signal could be generated from firmware. The processing unit 31 sequentially acquires a test instruction in the selected test program and converts the acquired test instruction into a test command, typically a hardware instruction code, in the course of the test flow. In this embodiment, the electronic device is an optical recording/reproducing device, so the converted test commands are preferably compatible with a well-known Integrated Drive Electronics/AT Attachment Packet Interface (IDE/ATAPI) specification. And then, the processing unit 31 generates a test message comprising the converted test command, a header comprising information regarding that this test message comprises a test command to be executed, and a checksum. The checksum is utilized to ensure that the test message is transmitted without error.

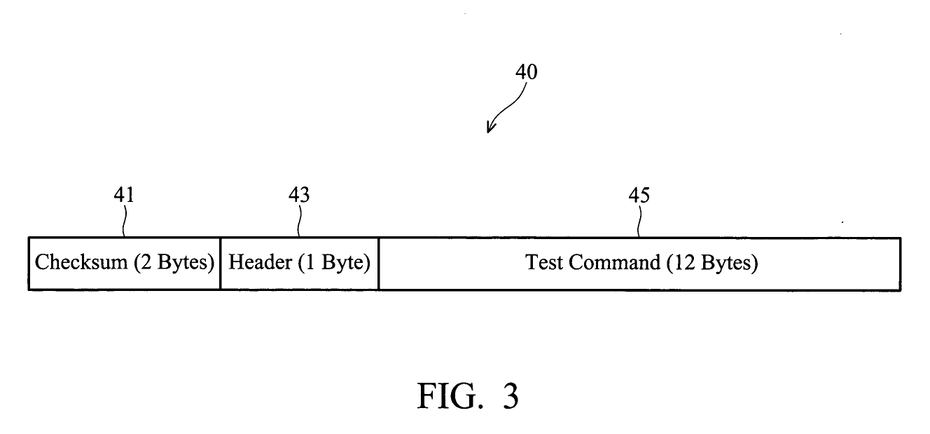

FIG. 3 is a diagram of an exemplary test message 40 comprising a two byte checksum 41, a one byte header 43 and a twelve byte test command 45. The processing unit 31 transmits the generated test message to the electronic device 23 (as shown in FIG. 2) via the connection port 37. The electronic device 23 then follows the order of the received test messages to execute the test commands therein.

Intermediary and final test results may be generated by the electronic device 23 (as shown in FIG. 2) during and/or after execution of test commands. Error messages may also be generated by the electronic device 23 when errors occur during execution of test commands. The generated test results and/or error messages are transmitted to the portable testing device through a connection port of the electronic device 23 (not shown) and the connection port 37. The processing unit 31 then stores the test results and/or error messages in the flash memory 33 or RAM 35. The received test results and/or error messages provided by the electronic device 23 are preferably stored in the flash memory 33 which retains test results and/or error messages after power-down for analysis by a computer.

The processing unit 31 directs the output module 39 to provide information about the received test results or error messages to notify an operator. The output module 39 may comprises a small liquid crystal display (LCD) screen to display information about the received test results and/or error messages in real-time. The output module 39 may comprise two lamps or Light Emitting Diodes (LEDs) utilized respectively to indicate test states such as normal and abnormal. For example, when a test result is received, the processing unit 31 directs a green lamp or a green LED to emit green light, notifying an operator that a test result is received. Alternatively, once an error message is received, the processing unit 31 directs a red lamp or a red LED to emit red light, notifying an operator that an error message is received. Besides, the output module 39 may also alarm when the processing unit 31 receives an error message.

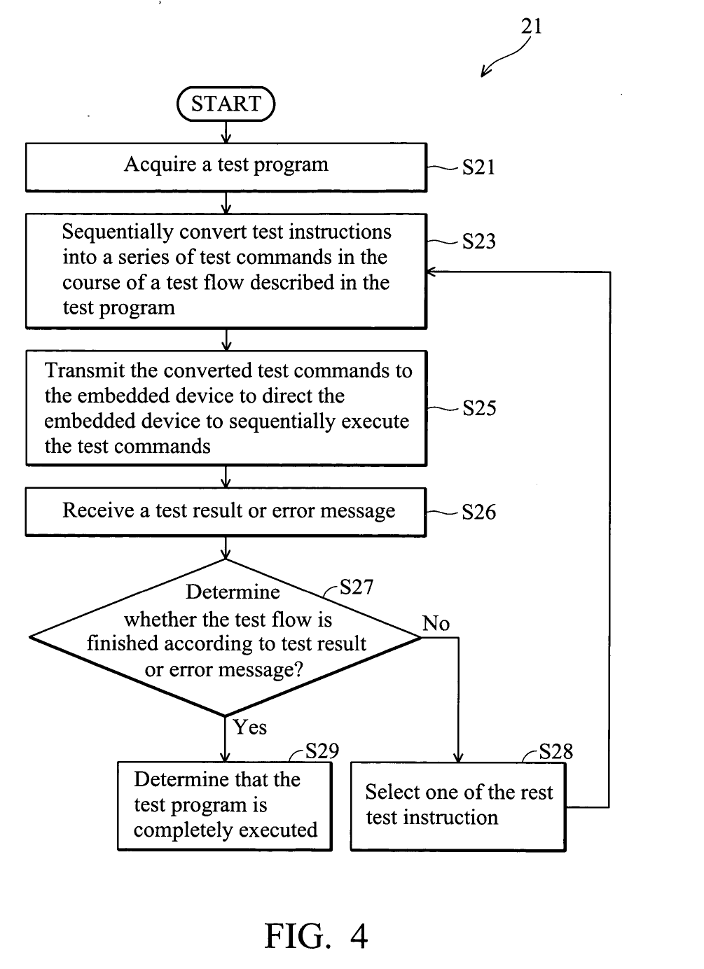

FIG. 4 illustrate a flowchart of an embodiment of a method for testing electronic devices. In step S21, a test program is acquired, describing a test flow including a series of test instructions. In step S23, one of the test instructions is converted into a test command recognized by the electronic device. In step S25, the converted test command is transmitted to the electronic device to direct the electronic device to execute the test commands. In step S26, a test result or error message is received. In step 27, judge whether the test flow is finished according to the test result or the error message. If yes, go to step 29. If no, go the step S28. In step 28, select one of the rest test instructions and go to step S23. In step 29, the test program is completely executed.

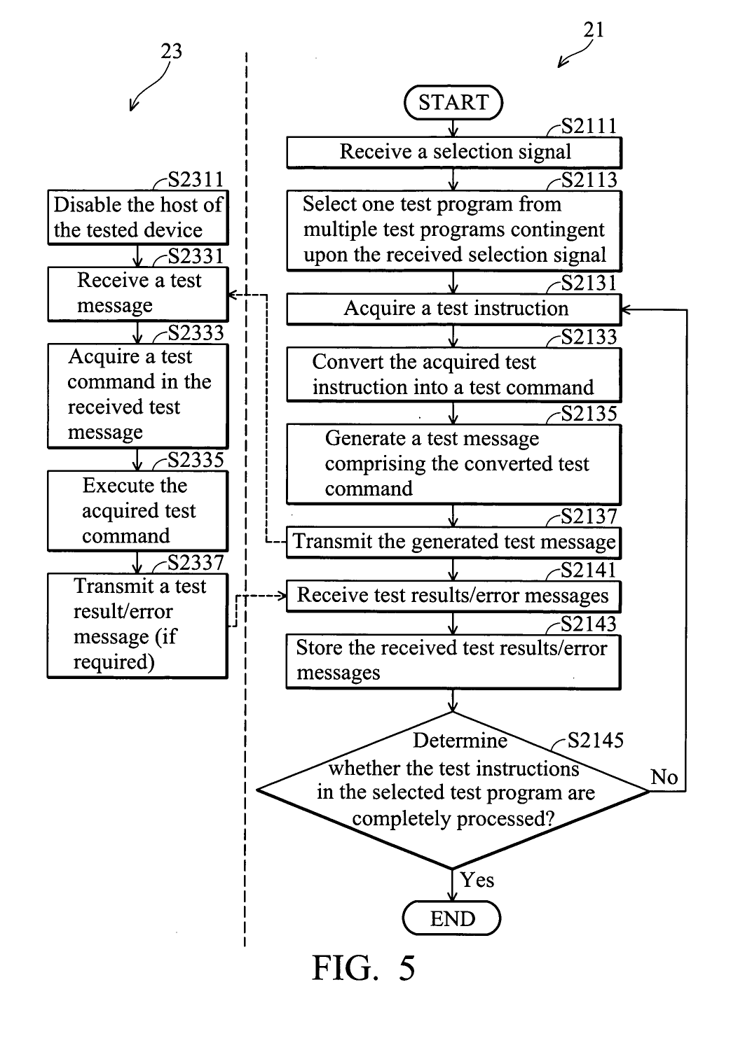

FIG. 5 illustrates a flowchart of an embodiment of a method for testing electronic devices divided into two sections, a left section showing steps performed by the electronic device 23 (as shown in FIG. 2), and a right section showing steps performed by the processing unit 31 of the portable test device 21 (as shown in FIG. 2), separated by dashed lines for added clarity.

In step S2111, a selection signal is received. In step S2113 one test program from multiple test programs is selected contingent upon the received selection signal. The test program describes a test flow including a series of test instructions. It will be understood one specific test flow among multiple predefined test flows is determined by the received selection signal, increasing test flexibility.

In step S2131, a test instruction is acquired in the course of the test flow described in the selected test program. In step S2133, the acquired test instruction is converted into a test command, typically a hardware instruction code. The converted test commands are preferably compatible with a well-known (IDE/ATAPI) specification when the portable testing device is used for testing the optical storage apparatus.

In step S2135, a test message comprising the converted test command is generated. Referring to FIG. 3, the test message further comprises a header comprising information regarding that this test message comprises a test command to be executed, and a checksum. The checksum is utilized to ensure that the test message is transmitted without error. In step S2137, the generated test message is transmitted to the electronic device 23.

In step S2331, the electronic device 23 receives a test message. In step S2333, a test command therein is acquired. Before acquiring the test command, the electronic device 23 validates the accuracy of the received test message via a checksum therein and determines that the message is a test message via the header information. In step S2335, the electronic device 23 executes the acquired test command. In step S2337, if required, a test result/error message is transmitted to the portable test device 21. Intermediary and final test results may be generated during and/or after execution of a test command. Error message may also be generated when error are occurred during execution of a test command.

In step S2141, the portable test device 21 receives the test result/error message. In step S2143, the received test result/error message is stored, preferably in a non-volatile memory device for further analysis. In step S2145, it is determined whether the test instructions in the selected test program are completely processed, and, if so, the process ends, and otherwise, the process proceeds to step S2131.

Systems and methods, or certain aspects or portions thereof, may take the form of program code (i.e., instructions) embodied in tangible media, such as floppy diskettes, CD-ROMS, hard drives, or any other machine-readable storage medium, wherein, when the program code is loaded into and executed by a machine, such as a computer system, mobile station, projector, displayer, mp3 player and the like, the machine becomes an apparatus for practicing the invention. The disclosed methods and apparatuses may also be embodied in the form of program code transmitted over some transmission medium, such as electrical wiring or cabling, through fiber optics, or via any other form of transmission, wherein, when the program code is received and loaded into and executed by a machine, such as a computer or an optical storage device, the machine becomes an apparatus for practicing the invention. When implemented on a general-purpose processor, the program code combines with the processor to provide a unique apparatus that operates analogously to specific logic circuits.

Certain terms are used throughout the description and claims to refer to particular system components. As one skilled in the art will appreciate, consumer electronic equipment manufacturers may refer to a component by different names. This document does not intend to distinguish between components that differ in name but not function.

Although the invention has been described in terms of preferred embodiment, it is not limited thereto. Those skilled in this technology can make various alterations and modifications without departing from the scope and spirit of the invention. Therefore, the scope of the invention shall be defined and protected by the following claims and their equivalents.

What is claimed is:

1. A portable device capable of testing an electronic device, comprising:
a connection port for establishing a connection between the portable device and the electronic device;
a memory for storing at least a test instruction describing a test command; and
a processing unit coupled to the memory device and the connection port, for acquiring the test instruction form the memory; and
transmitting the test command to the electronic device via the connection to direct the electronic device to execute the test command.

2. The portable device of claim 1 wherein the memory is a flash memory.

3. The portable device of claim 1 wherein the processing unit receives a test result or an error message generated by the electronic device and stores the received test result or error message in the memory.

4. The portable device of claim 3 further comprising an output module, wherein the processing unit directs the output module to provide information about the received test result or error message.

5. The portable device of claim 4 wherein the output module connected to a liquid crystal display (LCD) to display real-time information about the received test result or error message.

6. The portable device of claim 4 wherein the output module comprises at least a lamp or at least a Light Emitting Diode (LED), the processing unit directs the lamp or the LED to emit light when the test result or the error message is received.

7. The portable device of claim 1, further comprising a Random Access Memory (RAM) coupled to the processing unit for storing a test result or an error message received from the electronic device.

8. The portable device of claim 1 wherein the test command is compatible with an Integrated Drive Electronics/AT Attachment Packet Interface (IDE/ATAPI) specification.

9. The portable device of claim 1, wherein the connection port is compatible with RS232, Integrated Drive Electronics (IDE), Universal Serial Bus (USB) or Small Computer System Interface (SCSI).

10. A method for testing an electronic device, performed by a portable test device, comprising:
acquiring a test instruction describing a test command; and
transmitting the test command to the electronic device to direct the electronic device to execute the test command.

11. The method of claim 10, further comprising:
receiving a test result or an error message generated by the electronic device; and
storing the received test result or error message in a memory of the portable test device.

12. The method of claim 11, further comprising:
displaying the test result or the error message.

13. The method of claim 12, further comprising:
displaying real-time information about the received test result or the error message.

14. The method of claim 11, further comprising:
emitting light when the test result or the error message is received.

15. The method of claim 11, further comprising:
alarming when the error message is received.

16. The method of claim 11, wherein the memory is selected from the group consisted of a volatile memory and a non-volatile memory.

17. The method of claim 10, wherein the converted test command is compatible with an Integrated Drive Electronics/AT Attachment Packet Interface (IDE/ATAPI) specification.
